(19) United States
(12) Patent Application Publication
(10) Pub. No.: US 2014/0111939 A1
(43) Pub. Date: Apr. 24, 2014

(54) ELECTRONIC DEVICE WITH HEAT DISSIPATION MODULE

(71) Applicant: TAI-WEI LIN, New Taipei (TW)

(72) Inventor: TAI-WEI LIN, New Taipei (TW)

(21) Appl. No.: 13/688,471

(22) Filed: Nov. 29, 2012

(30) Foreign Application Priority Data
Oct. 18, 2012 (TW) 101138367

(51) Int. Cl. H05K 7/20

(52) U.S. Cl. CPC H05K 7/20136
USPC 361/695

(57) ABSTRACT

An electronic device includes a circuit board, a bracket, a number of sliding blocks, and a number of fans. The circuit board includes a number of sensors to test temperature of different areas of the circuit board. The bracket is located at a side of the circuit board. The sliding blocks are slidably mounted to the bracket. A chip is mounted in each sliding block and electrically connected to a corresponding sensor, to control the sliding block to slide according to signals from the sensor. The fans are respectively fastened to the sliding blocks. The chips receive the signals of the sensors and control the sliding blocks with the fans to slide toward areas having higher temperature than other areas.

### BACKGROUND

1. Technical Field

The present disclosure relates to an electronic device including a heat dissipation module.

2. Description of Related Art

In a server, a row of system fans is supplied to dissipate heat for electronic components of the motherboard. If the temperature of one of the areas of the motherboard increases, the corresponding fan usually speeds up to supply more airflow for the area. However, the noise generated by the high speed fan can be bothersome.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of an electronic device, wherein the electronic device includes a bracket, a plurality of sliding blocks, and a plurality of stopping doors.

FIG. 2 is an enlarged view of a circled portion II of FIG. 1.

FIG. 3 is a front plan view of the bracket, the sliding blocks, and the stopping doors of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

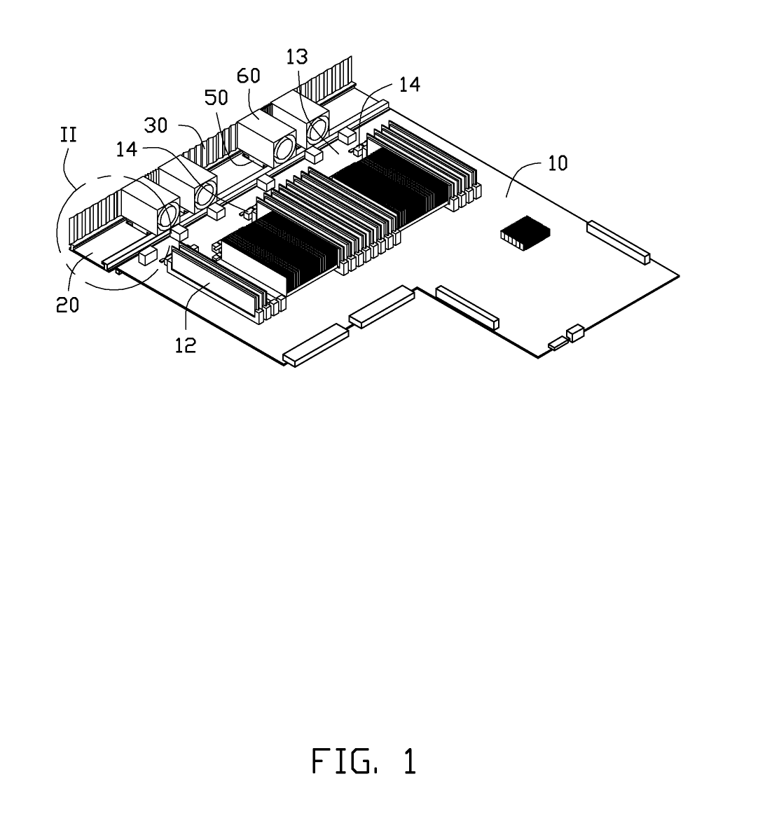

FIG. 1 shows an exemplary embodiment of an electronic device including a circuit board 10, a bracket 20, a plurality of foldable stopping doors 30, a plurality of sliding blocks 50, and a plurality of fans 60, respectively fastened on tops of the sliding blocks 50.

The circuit board 10 includes a plurality of electronic components 12, and a plurality of sensors 14 to test temperature of different areas 13 of the circuit board 10.

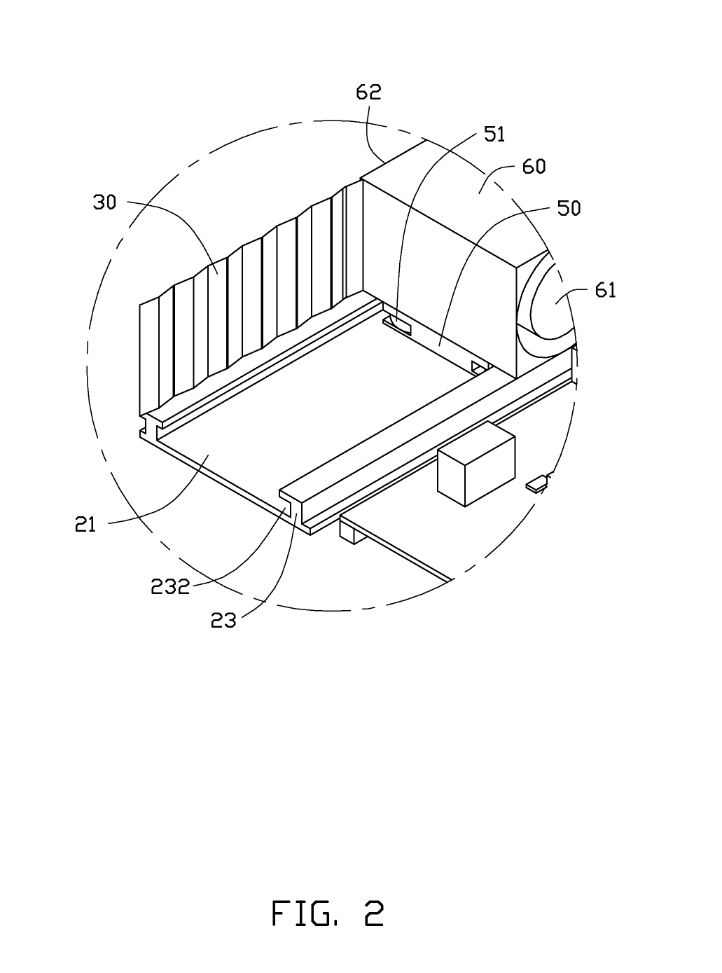

FIG. 2 shows the bracket 20 located at a side of the circuit board 10. The bracket 20 includes a bottom plate 21 and two rails 23 extending up from opposite sides of the bottom plate 21 and substantially parallel to the side of the circuit board 10. A slide slot 232 is defined in a side of each rail 23 facing the other rail 23.

The stopping doors 30 are mounted on a top of the rail 23 away from the circuit board 10. Each stopping door 30 can be folded or spread along a longitudinal direction of the rail 23.

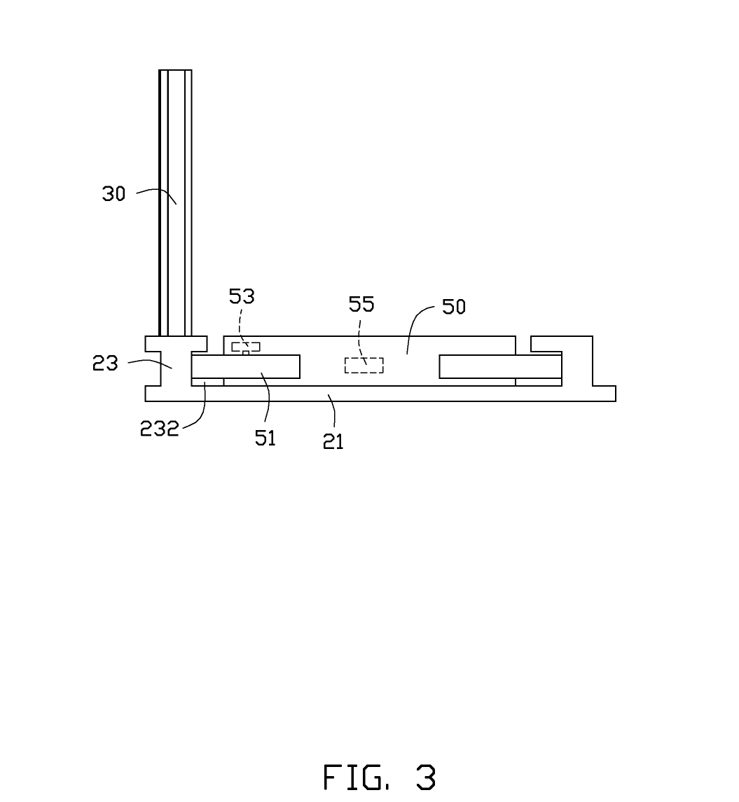

FIGS. 2 and 3 show each sliding block 50 placed on the bottom plate 21. The sliding block 50 includes four wheels 51 located four corners of the sliding block 50 to roll along the slide slots 232. A motor 53 is mounted in the sliding block 50 to drive one of the wheels 51. A chip 55, such as a single chip, is mounted in the sliding block 50 and electrically connected to the motor 53 and the sensors 14.

An airflow outlet 61 of the fan 60 faces the circuit board 10, and an airflow inlet 62 of the fan 60 is opposite to the circuit board 10. Portions of the fan 60 at opposite sides of the airflow inlet 62 are respectively fastened to two neighboring stopping doors 30 located at opposite sides of the fan 60.

When the temperature of one of the areas 13 is relatively high, the corresponding sensor 14 sends signals to the chip 55 of the sliding block 50 near the area 13. The chip 55 receives the signals and controls the corresponding motor 53 to drive the corresponding wheel 51 to roll. Therefore, the sliding block 50 slides along the bracket 20 and is gradually near the high temperature area 13. The fan 60 fastened to the sliding block 50 can supply more airflow for the high temperature area 13. As the signals of the sensors 14, the chips 55 control the sliding blocks 50 with the fans 60 to slide toward the areas 13 having higher temperature than other areas 13, thereby increasing the heat dissipation efficiency.

Obviously, when one of the fans 60 moves, one of the stopping doors 30 fastened to the fan 60 and opposite to the movement direction of the fan 60 spreads, and the other stopping door 30, fastened to the fan 60 and toward the movement direction of the fan 60, is folded. The stopping doors 30 can block the high temperature airflow from the circuit board 10 to flow to the airflow inlets 62 of the fans 60, thus avoid decreasing the heat dissipation efficiency of the fans 60.

It is believed that the present embodiments and their advantages will be understood from the foregoing description, and various changes may be made thereto without departing from the spirit and scope of the description or sacrificing all of their material advantages, the examples hereinbefore described merely being embodiments.

What is claimed is:

1. An electronic device, comprising:
a circuit board comprising a plurality of sensors to test temperature of different areas of the circuit board;
a bracket located at a side of the circuit board;
a plurality of sliding blocks slidably mounted to the bracket in a direction substantially parallel to the side of the circuit board, a chip mounted in each sliding block and electrically connected to a corresponding sensor, to control the sliding block to slide according to signals from the corresponding sensor; and
a plurality of fans respectively fastened to the plurality of sliding blocks;
wherein the chips receive the signals of the plurality of sensors and control the corresponding sliding blocks with the corresponding fans to slide toward areas having higher temperature than other areas.

2. The electronic device of claim 1, wherein the bracket comprises a bottom plate and two parallel rails extending up from opposite sides of the bottom plate, and each sliding block slides along the rails.

3. The electronic device of claim 2, wherein a slide slot is defined in a side of each rail facing the other rail, and each sliding block is placed on the bottom plate and comprises a plurality of wheels for rolling along the slide slots.

4. The electronic device of claim 3, wherein a motor is mounted in each sliding block and connected to one of the plurality of wheels, and the chip in the sliding block controls the motor to drive the one of the plurality of wheels to roll.

5. The electronic device of claim 2, further comprising a plurality foldable stopping doors mounted on a top of the rail away from the circuit board, wherein opposite sides of each fan are respectively fastened to two neighboring stopping doors located at opposite sides of the fan.
